(19) United States
(12) Patent Application Publication
(10) Pub. No.: US 2024/0268133 A1
(43) Pub. Date: Aug. 8, 2024

(54) MEMORY DEVICE AND MEMORY SYSTEM INCLUDING THE SAME

(71) Applicant: SAMSUNG ELECTRONICS CO., LTD., Suwon-si (KR)

(72) Inventors: Taehong KWON, Suwon-si (KR); Daeseok BYEON, Suwon-si (KR)

(73) Assignee: SAMSUNG ELECTRONICS CO., LTD., Suwon-si (KR)

(21) Appl. No.: 18/430,288

(22) Filed: Feb. 1, 2024

(30) Foreign Application Priority Data
Feb. 2, 2023 (KR) 10-2023-0014408

(51) Int. Cl. H10B 80/00; G11C 16/30; H01L 23/00; H01L 25/065; H01L 25/18

(52) U.S. Cl. CPC H10B 80/00; G11C 16/30; H01L 24/08; H01L 25/0657; H01L 25/18; H01L 2224/08145; H01L 2924/1431; H01L 2924/14511

(57) ABSTRACT

A memory device, including a first chip including a memory cell array; and a second chip bonded to the first chip and including a voltage generator configured to generate a voltage which is supplied to the memory cell array, wherein the second chip comprises a bonding pad connected to the voltage generator and bonded to an external charge pump.

### CROSS-REFERENCE TO RELATED APPLICATION

This application is based on and claims priority under 35 U.S.C. § 119 to Korean Patent Application No. 10-2023-0014408, filed on Feb. 2, 2023, in the Korean Intellectual Property Office, the disclosure of which is incorporated by reference herein in its entirety.

### BACKGROUND

### 1. Field

The disclosure relates to a memory device, and more particularly, to a memory device including a bonding pad connected to an external charge pump by a bonding manner and a memory system including the same.

### 2. Description of Related Art

Non-volatile memory devices, such as flash, may include word lines stacked on a substrate. In the word lines, capacitors inside the word lines may be charged by a charge pump inside the memory device.

When the number of word lines included in the memory device is increased to increase the capacity of the memory device, the capacity of the charge pump may also be increased. An increase in the capacity of the charge pump may be accompanied by an increase in the size of the charge pump. Therefore, when the capacity of the memory device is increased, the number of word lines may increase and the capacity of the charge pump may increase, so that the overall size of the memory device may greatly increase. Accordingly, there is a need for a method to address such a problem.

### SUMMARY

Provided is a memory device capable of minimizing an increase in the size of the memory device when increasing the capacity of the memory device.

Additional aspects will be set forth in part in the description which follows and, in part, will be apparent from the description, or may be learned by practice of the presented embodiments.

In accordance with an aspect of the disclosure, a memory device includes a first chip including a memory cell array; and a second chip bonded to the first chip and including a voltage generator configured to generate a voltage which is supplied to the memory cell array, wherein the second chip includes a bonding pad connected to the voltage generator and bonded to an external charge pump.

In accordance with an aspect of the disclosure, a memory device includes a first chip comprising a memory cell array; and a second chip bonded to the first chip; wherein the second chip includes a connection circuit supplied with an external voltage; and a voltage generator configured to generate a voltage which is supplied to the memory cell array based on the external voltage, wherein the connection circuit includes a plurality of bonding pads connected to the voltage generator, wherein each bonding pad of the plurality of bonding pads is bonded to a corresponding external charge pump from among a plurality of external charge pumps; a plurality of bonding pad switches configured to adjust a connection between the each bonding pad and the voltage generator; a wire pad connected to the voltage generator in parallel with the plurality of bonding pads, and connected to an external power management integrated circuit (PMIC); and a wire pad switch configured to adjust a connection between the wire pad and the voltage generator.

In accordance with an aspect of the disclosure, a memory system includes a memory controller; and a memory device configured to operate based on a command received from the memory controller, wherein the memory device includes a memory cell array; a connection circuit supplied with an external voltage; and a voltage generator configured to generate a voltage supplied to the memory cell array based on the external voltage, wherein the connection circuit includes a plurality of bonding pads connected to the voltage generator, wherein each bonding pad of the plurality of bonding pads is bonded to a corresponding external charge pump from among a plurality of external charge pumps; a plurality of bonding pad switches configured to adjust a connection between the each bonding pad and the voltage generator; a wire pad connected to the voltage generator in parallel with the plurality of bonding pads, and connected to an external power management integrated circuit (PMIC); and a wire pad switch configured to adjust a connection between the wire pad and the voltage generator.

### BRIEF DESCRIPTION OF THE DRAWINGS

The above and other aspects, features, and advantages of certain embodiments of the present disclosure will be more apparent from the following detailed description taken in conjunction with the accompanying drawings in which:

FIG. 1 is a block diagram illustrating a memory system according to an embodiment;

FIG. 2 is a block diagram illustrating a memory device according to an embodiment;

FIG. 3 is a diagram illustrating a structure of a memory device according to an embodiment;

FIG. 4 is a circuit diagram illustrating a memory block of a memory device according to an embodiment;

FIG. 5 is a circuit diagram illustrating an example of a connection circuit of a memory device according to an embodiment;

FIG. 6 is a circuit diagram illustrating an example in which a connection circuit of a memory device is connected to a charge pump, according to an embodiment;

FIG. 7 is a circuit diagram illustrating an example in which a connection circuit of a memory device is connected to a power management integrated circuit, according to an embodiment;

FIGS. 8 and 9 are perspective views illustrating the structure of the memory device shown in FIG. 5, according to an embodiment;

FIG. 10 is a circuit diagram illustrating another example of a connection circuit of a memory device according to an embodiment; and

FIGS. 11 and 12 are perspective views illustrating the structure of the memory device shown in FIG. 10, according to an embodiment.

### DETAILED DESCRIPTION

Hereinafter, embodiments concept are described in detail with reference to the accompanying drawings.

As is traditional in the field, the embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the present scope. Further, the blocks, units and/or modules of the embodiments may be physically combined into more complex blocks, units and/or modules without departing from the present scope.

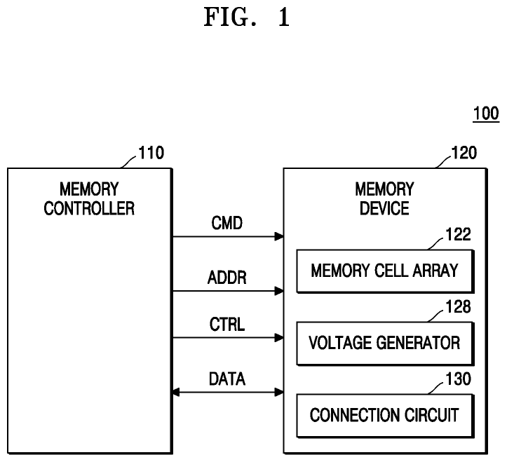

FIG. 1 is a block diagram illustrating a memory system according to an embodiment.

Referring to FIG. 1, a memory system 100 may include a memory controller 110 and at least one memory device 120. In the example illustrated in FIG. 1, although a plurality of conceptual hardware configurations included in the memory system 100 are shown, embodiments are not limited thereto, and other elements or configurations may be additionally included. The memory controller 110 may control the memory device 120 to write data into the memory device 120 in response to a write request from a host, or may control the memory device 120 to read data stored in the memory device 120 in response to a read request from the host.

In some embodiments, the memory system 100 may be an internal memory embedded in an electronic device. For example, the memory system 100 may be an embedded universal flash storage (UFS) memory device, an embedded multi-media card (eMMC), or a solid state drive (SSD). In some embodiments, the memory system 100 may be an external memory detachable from an electronic device. For example, the memory system 100 may include at least one of a UFS memory card, a compact flash (CF), secure digital (SD) card, a micro secure digital (Micro-SD) card, a mini secure digital (Mini-SD) card, an extreme digital (xD) card, and a memory stick.

The memory device 120 may perform an erase, program, or read operation under the control of the memory controller 110. The memory device 120 may receive a command CMD and an address ADDR from the memory controller 110 through an input/output line and transmits and receives data DATA for a program operation or a read operation with the memory controller 110. Also, the memory device 120 may receive a control signal CTRL through a control line. The memory device 120 may include a memory cell array 122, a voltage generator 128, and a connection circuit 130.

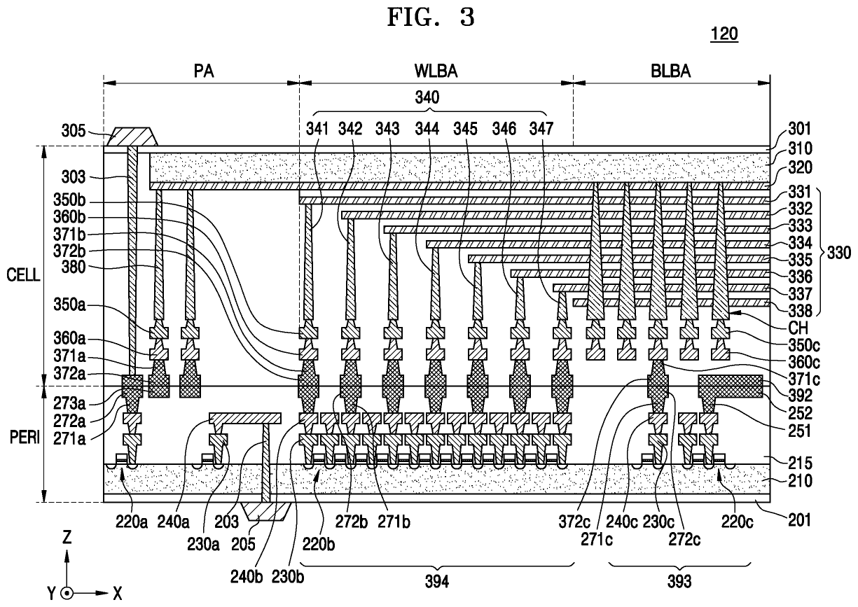

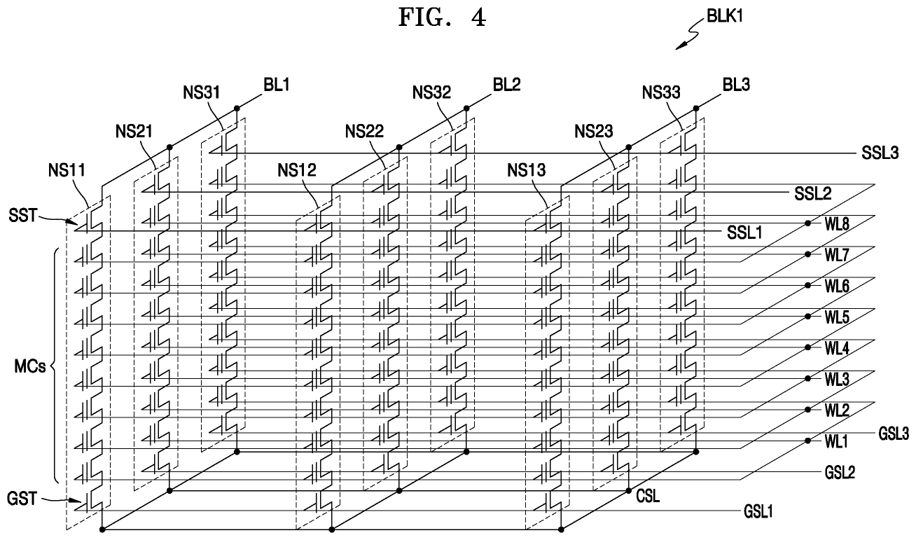

The memory cell array 122 may include a plurality of memory blocks, and each of the plurality of memory blocks may include a plurality of memory cells. For example, the plurality of memory cells may be flash memory cells. Hereinafter, embodiments in which the plurality of memory cells are NAND flash memory cells are described as an example, but embodiments are not limited thereto. The memory cell array 122 may include a three-dimensional memory cell array including a plurality of cell strings, as described below with reference to FIGS. 3 and 4.

A three-dimensional memory cell array may be monolithically formed on at least one physical level of the memory cell arrays having an active region disposed on a silicon substrate and circuitry formed on or in the substrate as a circuit related to operation of the memory cells. The term “monolithic” may mean that the layers of each level of the array are stacked directly on top of the layers of each lower level of the array. In an embodiment, a three-dimensional (3D) memory cell array may include cell strings arranged in the vertical direction such that at least one memory cell is located above another memory cell. The at least one memory cell may include a charge trap layer. U.S. Pat. Nos. 7,679,133, 8,553,466, 8,654,587, 8,559,235, and U.S. Patent Application Publication No. 2011/0233648, the disclosures of which are incorporated by reference herein in their entirety, disclose examples of configurations for a three-dimensional memory array in which the three-dimensional memory array is organized in multiple levels and word lines and/or bit lines are shared between the levels.

The voltage generator 128 may generate a voltage supplied to the memory cell array 122. The voltage generator 128 may generate various types of voltages for performing write, read, and erase operations on the memory cell array 122 based on the voltage control signal. For example, the voltage generator 128 may generate a word line voltage VWL, for example, a program voltage, a verify voltage, a read voltage, a pass voltage, an erase voltage, an erase verify voltage, and the like. Also, in an incremental step pulse programming (ISPP) program operation, the voltage generator 128 may generate a plurality of program voltages and a plurality of verify voltages having different voltage levels. In an embodiment, the voltage generator 128 may generate a voltage supplied to the memory cell array 122 based on the external voltage supplied from the connection circuit 130.

The connection circuit 130 may receive an external voltage from the outside of the memory device 120. For example, the connection circuit 130 may receive an external voltage from a charge pump or a power management integrated circuit (PMIC) external to the memory device 120 and transfer the supplied external voltage to the voltage generator 128.

The connection circuit 130 may include a bonding pad, a bonding pad switch, a wire pad, a wire pad switch, and an auxiliary bonding pad.

The bonding pad may be connected to the charge pump external to the memory device 120 through a bonding manner. In embodiments, two elements which are connected to each other through a bonding manner may be described as being bonded to each other. Accordingly, the bonding pad may be bonded to the charge pump external to the memory device 120. Accordingly, the connection circuit 130 may receive an external voltage from the external charge pump through the bonding pad and transfer the external voltage to the voltage generator 128.

The bonding pad switch may adjust a connection between the bonding pad and the voltage generator. When the voltage generator 128 receives external voltage from the external charge pump to operate, the bonding pad switch may connect the bonding pad to the voltage generator. Conversely, when the voltage generator 128 operates by receiving an external voltage from the external PMIC, the bonding pad switch may open a connection between the bonding pad and the voltage generator. In embodiments, opening a connection between to elements may be referred to as disconnecting the two elements. Accordingly, when the voltage generator 128 operates by receiving an external voltage from the external PMIC, the bonding pad switch may disconnect the bonding pad from the voltage generator. In embodiments, the terms “disconnect” or “disconnecting” may be used to indicate that a connection is opened or broken between two elements which are connected, and may also be used to indicate that a new connection is not established (e.g. that a disconnection is maintained) between two elements which are not connected.

The wire pad may be connected to the PMIC outside the memory device 120. Accordingly, the connection circuit 130 may receive an external voltage from the external PMIC through the wire pad and transfer the external voltage to the voltage generator 128.

The wire pad switch may adjust the connection between the wire pad and the voltage generator. When the voltage generator 128 operates by receiving an external voltage from the external charge pump, the wire pad switch may open a connection between the wire pad and the voltage generator, or for example disconnect the wire pad and the voltage generator. Conversely, when the voltage generator 128 operates by receiving an external voltage from the PMIC, the wire pad switch may connect the wire pad to the voltage generator.

The auxiliary bonding pad may be connected to an auxiliary charge pump external to the memory device 120 through a bonding manner. Accordingly, the connection circuit 130 may receive an external voltage from the external auxiliary charge pump through the auxiliary bonding pad and transfer the external voltage to peripheral circuits other than the voltage generator 128 in the memory device 120.

As described above, the memory system 100 according to an embodiment may include a bonding pad connected to the voltage generator 128 and connected to the external charge pump in a bonding manner, and the charge pump may be positioned outside of the memory device 120, thereby minimizing an increase in size of the memory device 120 due to an increase in capacity of the memory device 120.

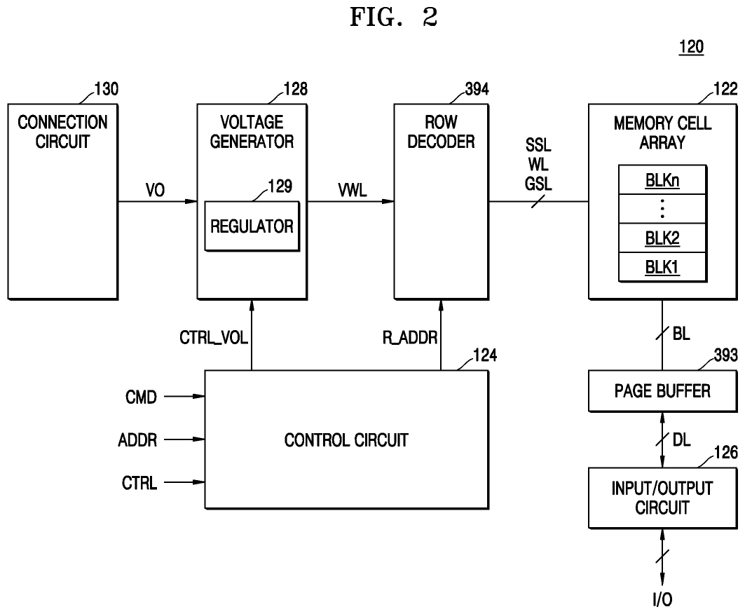

FIG. 2 is a block diagram illustrating a memory device according to an embodiment.

Referring to FIG. 2, a memory device 120 may include a memory cell array 122, a row decoder 394, a control circuit 124, a page buffer 393, an input/output circuit 126, a voltage generator 128, and a connection circuit 130. In embodiments, the memory device 120 may further include an input/output interface.

The memory cell array 122 may be connected to word lines WL, string select lines SSL, ground select lines GSL, and bit lines BL. The memory cell array 122 may be connected to the row decoder 394 through word lines WL, string select lines SSL, and ground select lines GSL and connected to the page buffer 393 through bit lines BL. The memory cell array 122 may include a plurality of memory blocks BLK1 to BLKn.

Each memory block BLK1 to BLKn may include a plurality of memory cells and a plurality of selection transistors. The memory cells may be connected to the word lines WL, and the select transistors may be connected to the string select lines SSL or the ground select lines GSL. The memory cells of each memory block BLK1 to BLKn may include single-level cells storing 1-bit data or multi-level cells storing M-bit data, where M is an integer greater than 2.

The row decoder 394 may select one of the plurality of memory blocks BLK1 to BLKn of the memory cell array 122, may select one of the word lines WL of the selected memory block, and may select one of the plurality of string select lines SSL.

The control circuit 124 may output various internal control signals for performing program, read, and erase operations on the memory cell array 122 based on a command CMD, an address ADDR, and a control signal CTRL transmitted from the memory controller 110. The control circuit 124 may provide a row address R_ADDR to the row decoder 394, may provide a column address to the input/output circuit 126, and may provide a voltage control signal CTRL_VOL to the voltage generator 128.

The page buffer 393 may operate as a write driver or as a sense amplifier depending on an operation mode. During a read operation, the page buffer 393 may sense the bit line BL of the selected memory cell under the control of the control circuit 124. The sensed data may be stored in latches provided inside the page buffer 393. The page buffer 393 may dump data stored in the latches to the input/output circuit 126 through a data line DL under the control of the control circuit 124.

The input/output circuit 126 may temporarily store the command CMD, the address ADDR, and the data DATA provided from the outside of the memory device 120 through an input/output line I/O. The input/output circuit 126 may temporarily store read data of the memory device 120 and output the read data to the outside through the input/output line I/O at a designated time point.

The voltage generator 128 may generate a voltage supplied to the memory cell array 122. The voltage generator 128 may generate various types of voltages for performing write, read, and erase operations on the memory cell array 122 based on the voltage control signal CTRL_VOL. For example, the voltage generator 128 may generate a word line voltage VWL, for example, a program voltage, a verify voltage, a read voltage, a pass voltage, an erase voltage, an erase verify voltage, and the like.

The voltage generator 128 may include a regulator 129. The regulator 129 may generate at least one word line voltage VWL by controlling an external voltage supplied through the connection circuit 130. The regulator 129 may output the generated at least one word line voltage VWL to the row decoder 394.

The connection circuit 130 may receive an external voltage from the outside of the memory device 120. The connection circuit 130 may receive an external voltage from a charge pump or a PMIC external to the memory device 120 and transfer the supplied external voltage to the voltage generator 128.

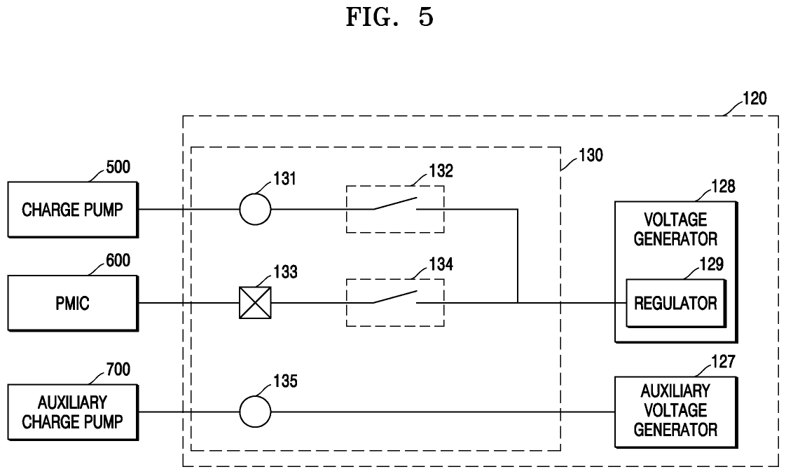

An example of a more detailed structure of the connection circuit 130 and the connection relationship with the voltage generator 128 of the connection circuit 130 are described below with reference to FIG. 5 and subsequent drawings.

FIG. 3 is a diagram illustrating a structure of a memory device according to an embodiment.

Referring to FIG. 3, a memory device 120 may have a chip-to-chip (C2C) structure. The C2C structure may refer to a structure formed by manufacturing an upper chip including a cell region CELL on a first wafer, manufacturing a lower chip including a peripheral circuit region PERI on a second wafer, different from the first wafer, and then connecting the upper chip to the lower chip in a bonding manner, for example by bonding the upper chip with the lower chip. In embodiments, the bonding manner may include a method of electrically connecting a bonding metal formed on an uppermost metal layer of the upper chip to a bonding metal formed on an uppermost metal layer of the lower chip. For example, when the bonding metals are formed of copper (Cu), the bonding manner may be a Cu—Cu bonding and the bonding metals may also be formed of aluminum or tungsten.

Each of the peripheral circuit region PERI and the cell region CELL of the memory device 40 may include an external pad bonding area PA, a word line bonding area WLBA, and a bit line bonding area BLBA.

The peripheral circuit region PERI may include a first substrate 210, an interlayer insulating layer 215, a plurality of circuit elements 220a, 220b, and 220c formed on the first substrate 210, first metal layers 230a, 230b, and 230c respectively connected to the plurality of circuit elements 220a, 220b, and 220c, and second metal layers 240a, 240b, and 240c formed on the first metal layers 230a, 230b, and 230c. In an example embodiment, the first metal layers 230a, 230b, and 230c may be formed of tungsten having relatively high resistance and the second metal layers 240a, 240b, and 240c may be formed of copper having relatively low resistance.

Although the example memory device 120 is illustrated in FIG. 3 as including the first metal layers 230a, 230b, and 230c and the second metal layers 240a, 240b, and 240c embodiments are not limited thereto, and one or more metal layers may be further formed on the second metal layers 240a, 240b, and 240c. At least a portion of the one or more metal layers formed on the second metal layers 240a, 240b, and 240c may be formed of aluminum or the like having a lower resistance than those of copper forming the second metal layers 240a, 240b, and 240c.

The interlayer insulating layer 215 may be disposed on the first substrate 210 and may be on or cover the plurality of circuit elements 220a, 220b, and 220c, the first metal layers 230a, 230b, and 230c, and the second metal layers 240a, 240b, and 240c. The interlayer insulating layer 215 may include an insulating material such as silicon oxide, silicon nitride, or the like.

Lower bonding metals 271b and 272b may be formed on the second metal layer 240b in the word line bonding area WLBA. In the word line bonding area WLBA, the lower bonding metals 271b and 272b in the peripheral circuit region PERI may be electrically connected to upper bonding metals 371b and 372b in the cell region CELL in a bonding manner, and the lower bonding metals 271b and 272b and the upper bonding metals 371b and 372b may be formed of aluminum, copper, tungsten, or the like.

The cell region CELL may include at least one memory block. The cell region CELL may include a second substrate 310 and a common source line 320. On the second substrate 310, a plurality of word lines 330, which may include for example word lines 331 to 338, may be stacked in a direction (for example the Z-axis direction), perpendicular to an upper surface of the second substrate 310. At least one string select line and at least one ground select line may be arranged on and below the plurality of word lines 330, respectively, and the plurality of word lines 330 may be disposed between the at least one string select line and the at least one ground select line.

In the bit line bonding area BLBA, a channel structure CH may extend in a direction, perpendicular to the upper surface of the second substrate 310, and pass through the plurality of word lines 330, the at least one string select line, and the at least one ground select line. The channel structure CH may include a data storage layer, a channel layer, a buried insulating layer, and the like, and the channel layer may be electrically connected to a first metal layer 350c and a second metal layer 360c. For example, the first metal layer 350c may be a bit line contact, and the second metal layer 360c may be, or may include, a bit line. In an example embodiment, the second metal layer 360c including the bit line may extend in a first direction (for example a Y-axis direction), parallel to the upper surface of the second substrate 310.

In an example embodiment illustrated in FIG. 3, an area in which the channel structure CH, the second metal layer 360c including the bit line, and the like are disposed may be defined as the bit line bonding area BLBA. In the bit line bonding area BLBA, the second metal layer 360c including the bit line may be electrically connected to the circuit elements 220c providing a page buffer 393 in the peripheral circuit region PERI. For example, the second metal layer 360c including the bit line may be connected to upper bonding metals 371c and 372c in the cell region CELL, and the upper bonding metals 371c and 372c may be connected to lower bonding metals 271c and 272c connected to the circuit elements 220c of the page buffer 393.

In the word line bonding area WLBA, the plurality of word lines 330 may extend in a second direction (for example the X-axis direction), parallel to the upper surface of the second substrate 310, and may be connected to a plurality of cell contact plugs 340, which may include cell contact plugs 341 to 347. The plurality of word lines 330 and the plurality of cell contact plugs 340 may be connected to each other in pads provided by at least a portion of the plurality of word lines 330 extending in different lengths in the second direction. A first metal layer 350b and a second metal layer 360b may be connected to an upper portion of the plurality of cell contact plugs 340 connected to the plurality of word lines 330, sequentially. The plurality of cell contact plugs 340 may be connected to the peripheral circuit region PERI by the upper bonding metals 371b and 372b of the cell region CELL and the lower bonding metals 271b and 272b of the peripheral circuit region PERI in the word line bonding area WLBA.

The plurality of cell contact plugs 340 may be electrically connected to the circuit elements 220b, which may be included in the row decoder 394 in the peripheral circuit region PERT. In an example embodiment, operating voltages of the circuit elements 220b providing the row decoder 394 may be different than operating voltages of the circuit elements 220c, which may be included in the page buffer 393. For example, operating voltages of the circuit elements 220c providing the page buffer 393 may be greater than operating voltages of the circuit elements 220b providing the row decoder 394.

A common source line contact plug 380 may be disposed in the external pad bonding area PA. The common source line contact plug 380 may be formed of a conductive material such as a metal, a metal compound, polysilicon, or the like, and may be electrically connected to the common source line 320. A first metal layer 350a and a second metal layer 360a may be stacked on an upper portion of the common source line contact plug 380, sequentially. For example, an area in which the common source line contact plug 380, the first metal layer 350a, and the second metal layer 360a are disposed may be referred to as the external pad bonding area PA.

Input-output pads 205 and 305 may be disposed in the external pad bonding area PA. Referring to FIG. 3, a lower insulating film 201 covering a lower surface of the first substrate 210 may be formed below the first substrate 210, and the first input-output pad 205 may be formed on the lower insulating film 201. The first input-output pad 205 may be connected to at least one of the plurality of circuit elements 220a, 220b, and 220c disposed in the peripheral circuit region PERI through a first input-output contact plug 203, and may be separated from the first substrate 210 by the lower insulating film 201. In addition, a side insulating film may be disposed between the first input-output contact plug 203 and the first substrate 210 to electrically separate the first input-output contact plug 203 and the first substrate 210.

Referring to FIG. 3, an upper insulating layer 301 covering the upper surface of the second substrate 310 may be formed on the second substrate 310, and the second input-output pad 305 may be disposed on the upper insulating layer 301. In embodiments, the upper insulating layer 301 may be referred to as an upper insulating film. The second input-output pad 305 may be connected to at least one of the plurality of circuit elements 220a, 220b, and 220c disposed in the peripheral circuit region PERI through a second input-output contact plug 303.

According to embodiments, the second substrate 310 and the common source line 320 may not be disposed in an area in which the second input-output contact plug 303 is disposed. Also, the second input-output pad 305 may not overlap the word lines 330 in the direction (for example the Z-axis direction) perpendicular to an upper surface of the second substrate 310. Referring to FIG. 3, the second input-output contact plug 303 may be separated from the second substrate 310 in a direction (for example the X-axis direction) parallel to the upper surface of the second substrate 310, and may pass through the interlayer insulating layer 315 of the cell region CELL to be connected to the second input-output pad 305.

According to embodiments, the first input-output pad 205 and the second input-output pad 305 may be selectively formed. For example, the memory device 120 may include only the first input-output pad 205 disposed on the first substrate 210 or the second input-output pad 305 disposed on the second substrate 310. In embodiments, the memory device 120 may include both the first input-output pad 205 and the second input-output pad 305.

A metal pattern in an uppermost metal layer may be provided as a dummy pattern or the uppermost metal layer may be absent, in each of the external pad bonding area PA and the bit line bonding area BLBA, respectively included in the cell region CELL and the peripheral circuit region PERI.

In the external pad bonding area PA, the memory device 120 may include a lower metal pattern 273a, corresponding to an upper metal pattern 372a formed in an uppermost metal layer of the cell region CELL, and having the same shape as the upper metal pattern 372a of the cell region CELL, in an uppermost metal layer of the peripheral circuit region PERI. In the peripheral circuit region PERI, the lower metal pattern 273a formed in the uppermost metal layer of the peripheral circuit region PERI may not be connected to a contact. Similarly, in the external pad bonding area PA, an upper metal pattern 372a, corresponding to the lower metal pattern 273a formed in an uppermost metal layer of the peripheral circuit region PERI, and having the same shape as a lower metal pattern 273a of the peripheral circuit region PERI, may be formed in an uppermost metal layer of the cell region CELL.

The lower bonding metals 271b and 272b may be formed on the second metal layer 240b in the word line bonding area WLBA. In the word line bonding area WLBA, the lower bonding metals 271b and 272b of the peripheral circuit region PERI may be electrically connected to the upper bonding metals 371b and 372b of the cell region CELL by a Cu—Cu bonding.

Furthermore, in the bit line bonding area BLBA, an upper metal pattern 392, corresponding to a lower metal pattern 252 formed in the uppermost metal layer of the peripheral circuit region PERI, and having the same shape as the lower metal pattern 252 of the peripheral circuit region PERI, may be formed in an uppermost metal layer of the cell region CELL. A contact may not be formed on the upper metal pattern 392 formed in the uppermost metal layer of the cell region CELL.

In an example embodiment, corresponding to a metal pattern formed in an uppermost metal layer in one of the cell region CELL and the peripheral circuit region PERI, a reinforcement metal pattern having the same shape as the metal pattern may be formed in an uppermost metal layer in another one of the cell region CELL and the peripheral circuit region PERI, and a contact may not be formed on the reinforcement metal pattern.

FIG. 4 is a circuit diagram illustrating a memory block of a memory device according to an embodiment.

The memory block shown in FIG. 4 may be an example of one of the plurality of memory blocks BLK1 to BLKn described with reference to FIG. 2, for example a first memory block BLK1. Hereinafter, embodiments are described in detail using the first memory block BLK1 as an example. The first memory block BLK1 may represent a 3D memory block formed in a 3D structure on a substrate. A plurality of memory cell strings included in the first memory block BLK1 may be formed in a direction perpendicular to the substrate.

Referring to FIG. 4, the first memory block BLK1 may include NAND strings NS11 to NS33, word lines WL1 to WL8, bit lines BL1 to BL3, ground select lines GSL1 to GSL3, string select lines SSL1 to SSL3, and a common source line CSL. Although FIG. 4 illustrates each of the cell strings NS11 to NS33 as including eight memory cells MCs connected to eight word lines WL1 to WL8, embodiments are not limited thereto.

Each cell string (e.g., the cell string NS11) may include a string select transistor SST, a plurality of memory cells MC, and a ground select transistor GST connected in series. The string select transistor SST is connected to the corresponding string select line SSL1. Each of the plurality of memory cells MC may be connected to corresponding word lines WL1 to WL8. The ground select transistor GST is connected to a corresponding ground select line GSL1. The string select transistor SST may be connected to the corresponding bit lines BL1 to BL3, and the ground select transistor GST may be connected to the common source line CSL.

According to embodiments, in each cell string, one or more dummy memory cells may be provided between the string select transistor SST and the memory cells MC. In each cell string, one or more dummy memory cells may be provided between the ground select transistor GST and the memory cells MC. In each cell string, one or more dummy memory cells may be provided between the memory cells MC. The dummy memory cells may have the same structure as the memory cells MC and may be unprogrammed (e.g., program inhibited) or programmed differently from the memory cells MC. For example, when the memory cells MC are programmed to have two or more threshold voltage distributions, the dummy memory cells may be programmed to have one threshold voltage distribution range or a threshold voltage distribution less than that of the memory cells MC.

FIG. 5 is a circuit diagram illustrating an example of a connection circuit of a memory device according to an embodiment.

Referring to FIG. 5, a connection circuit 130 according to an embodiment may include a bonding pad 131, a bonding pad switch 132, a wire pad 133, a wire pad switch 134, and an auxiliary bonding pad 135.

The bonding pad 131 may be connected to a voltage generator 128. Because the bonding pad 131 may be connected to the voltage generator 128, an external voltage supplied from a charge pump 500 outside the memory device 120 may be transferred to the voltage generator 128 through the bonding pad 131. The external voltage supplied through the bonding pad 131 may be transferred to a regulator 129 of the voltage generator 128.

The bonding pad 131 may be connected to the charge pump 500 through a bonding manner. In an embodiment, when the bonding pad 131 is formed of copper, the bonding manner may be a Cu—Cu bonding manner and the bonding pad 131 may also be formed of aluminum or tungsten. For example, the bonding pad 131 may be bonded to the charge pump 500 using Cu—Cu bonding.

The bonding pad switch 132 may be between the bonding pad 131 and the voltage generator 128. One end of the bonding pad switch 132 may be connected to the bonding pad 131 and the other end thereof may be connected to the voltage generator 128.

The bonding pad switch 132 may adjust a connection between the bonding pad 131 and the voltage generator 128. The bonding pad switch 132 may connect or disconnect the bonding pad 131 and the voltage generator 128.

The bonding pad switch 132 may adjust a connection between the bonding pad 131 and the voltage generator 128 based on whether the voltage generator 128 receives external voltage from the charge pump 500 to operate. For example, when the memory device 120 is included in a device that does not include the PMIC 600, such as a mobile device, the voltage generator 128 may operate by receiving an external voltage from the charge pump 500. As another example, when the memory device 120 is included in a device including the PMIC 600, such as an SSD, the voltage generator 128 may operate by receiving an external voltage supplied from the PMIC 600 instead of the charge pump 500.

When the voltage generator 128 receives voltage from the charge pump 500 to operate, the bonding pad switch 132 may connect the bonding pad 131 to the voltage generator 128. Conversely, when the voltage generator 128 receives voltage from the PMIC 600 to operate, the bonding pad switch 132 may open a connection between the bonding pad 131 and the voltage generator 128, or for example may disconnect the bonding pad 131 from the voltage generator 128.

The bonding pad switch 132 may adjust a connection between the bonding pad 131 and the voltage generator 128 based on a command received from an external controller. The bonding pad switch 132 may adjust a connection between the bonding pad 131 and the voltage generator 128 based on a command received from a controller that controls a device including the memory system 100.

For example, when the memory device 120 is included in a device that does not include the PMIC 600, such as a mobile device, the command received from the corresponding device may be a command for controlling the bonding pad switch 132 to connect the bonding pad 131 and the voltage generator 128, and accordingly, the bonding pad switch 132 may connect the bonding pad 131 to the voltage generator 128.

Conversely, when the memory device 120 is included in a device including the PMIC 600, such as an SSD, the command received from the corresponding device may be a command for controlling the bonding pad switch 132 to disconnect the bonding pad 131 from the voltage generator 128, and accordingly, the bonding pad switch 132 may be open between the bonding pad 131 and the voltage generator 128.

The wire pad 133 may be connected to the voltage generator 128 in parallel with the bonding pad 131. The wire pad 133 may be connected to the external PMIC 600. Because the wire pad 133 may be connected to the voltage generator 128, the external voltage supplied from the PMIC 600 outside the memory device 120 may be transferred to the voltage generator 128 through the wire pad 133. The external voltage supplied through the wire pad 133 may be transferred to the regulator 129 of the voltage generator 128.

The wire pad switch 134 may be between the wire pad 133 and the voltage generator 128. One end of the wire pad switch 134 may be connected to the wire pad 133 and the other end of the wire pad switch 134 may be connected to the voltage generator 128.

The wire pad switch 134 may adjust a connection between the wire pad 133 and the voltage generator 128. The wire pad switch 134 may connect or disconnect the wire pad 133 and the voltage generator 128.

The wire pad switch 134 may adjust a connection between the wire pad 133 and the voltage generator 128 based on whether the voltage generator 128 receives external voltage from the PMIC 600 to operate.

When the voltage generator 128 receives voltage from the PMIC 600 to operate, the wire pad switch 134 may connect the wire pad 133 to the voltage generator 128. Conversely, when the voltage generator 128 receives voltage from the charge pump 500 to operate, the wire pad switch 134 may disconnect the wire pad 133 from the voltage generator 128.

The wire pad switch 134 may adjust a connection between the wire pad 133 and the voltage generator 128 based on a command received from an external controller. The wire pad switch 134 may adjust a connection between the wire pad 133 and the voltage generator 128 based on a command received from a controller that controls a device including the memory system 100.

For example, when the memory device 120 is included in a device including the PMIC 600, such as an SSD, the command received from the corresponding device may be a command for controlling the wire pad switch 134 to connect the wire pad 133 and the voltage generator 128, and based on the command, the wire pad switch 134 may connect the wire pad 133 to the voltage generator 128.

Conversely, when the memory device 120 is included in a device that does not include the PMIC 600, such as a mobile device, the command received from the corresponding device may be a command for controlling the wire pad switch 134 to disconnect the wire pad 133 from the voltage generator 128, and based on the command, the wire pad switch 134 may be open between the wire pad 133 and the voltage generator 128.

The auxiliary bonding pad 135 may be connected to the auxiliary voltage generator 127 included in the memory device 120. The auxiliary voltage generator 127 may generate a voltage supplied to peripheral circuits included in the memory device 120. Accordingly, voltage may be supplied to peripheral circuits included in the memory device 120.

Because the auxiliary bonding pad 135 may be connected to the auxiliary voltage generator 127, an external voltage supplied from an auxiliary charge pump 700 external to the memory device 120 may be transferred to peripheral circuits through the auxiliary bonding pad 135 and the auxiliary voltage generator 127.

The auxiliary bonding pad 135 may be connected to the external auxiliary charge pump 700 through a bonding manner. In an embodiment, when the auxiliary bonding pad 135 is formed of copper, the bonding manner may be a Cu—Cu bonding manner and the auxiliary bonding pad 135 may also be formed of aluminum or tungsten. For example, the auxiliary bonding pad 135 may be bonded to the auxiliary charge pump 700 using Cu—Cu bonding.

As described above, the memory system 100 according to an embodiment may include a bonding pad 131 connected to the voltage generator 128 and connected to the external charge pump 500 in a bonding manner, and the charge pump 500 may be positioned outside the memory device 120, thereby minimizing an increase in size of the memory device 120 due to an increase in capacity of the memory device 120.

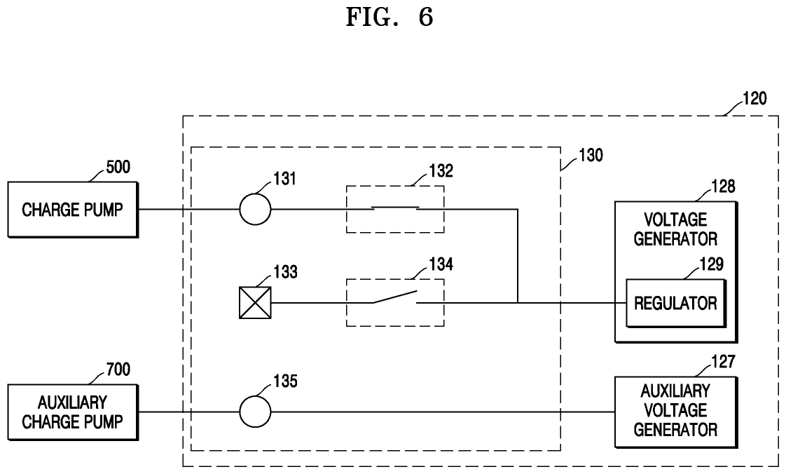

FIG. 6 is a circuit diagram illustrating an example in which a connection circuit of a memory device according to an embodiment is connected to a charge pump.

Referring to FIG. 6, in an embodiment in which a memory device 120 is included in a device that does not include a PMIC 600, such as a mobile device, the state of a connection circuit 130 may be determined.

In the embodiment of FIG. 6, a bonding pad 131 may be connected to a charge pump 500 through a bonding manner. In this case, the wire pad 133 may not be connected to the PMIC 600 because the device including the memory device 120 may not include the PMIC 600.

The bonding pad switch 132 may connect the bonding pad 131 to a regulator 129 of the voltage generator 128. Accordingly, the external voltage supplied from the charge pump 500 may be transferred to the regulator 129 through the bonding pad 131 and the bonding pad switch 132. Also, a wire pad switch 134 may be open between the wire pad 133 and the regulator 129 of the voltage generator 128.

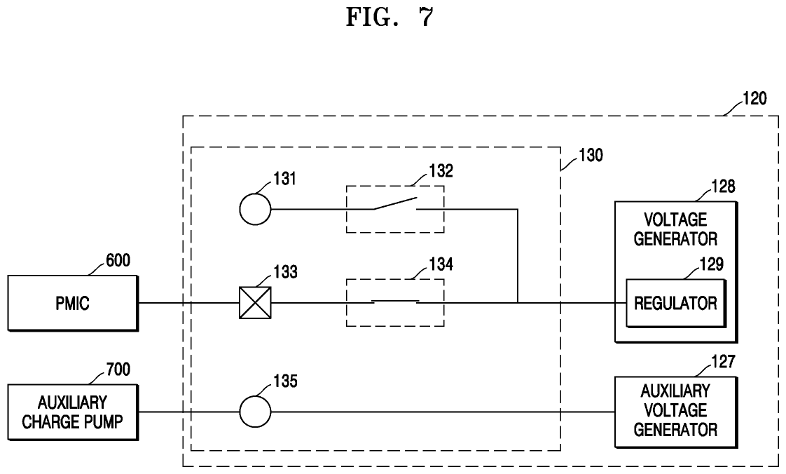

FIG. 7 is a circuit diagram illustrating an example in which a connection circuit of a memory device according to an embodiment is connected to a PMIC.

Referring to FIG. 7, in an embodiment in which the memory device 120 is included in a device including a PMIC 600, such as an SSD, the state of a connection circuit 130 may be determined.

In the embodiment of FIG. 7, a wire pad 133 may be connected to the PMIC 600 because the device including the memory device 120 may include the PMIC 600. In this case, the bonding pad 131 may not be connected to the charge pump 500.

A wire pad switch 134 may connect the wire pad 133 to a regulator 129 of a voltage generator 128. Accordingly, the external voltage supplied from the PMIC 600 may be transmitted to the regulator 129 through the wire pad 133 and the wire pad switch 134. Also, a bonding pad switch 132 may be open between the bonding pad 131 and the regulator 129 of the voltage generator 128.

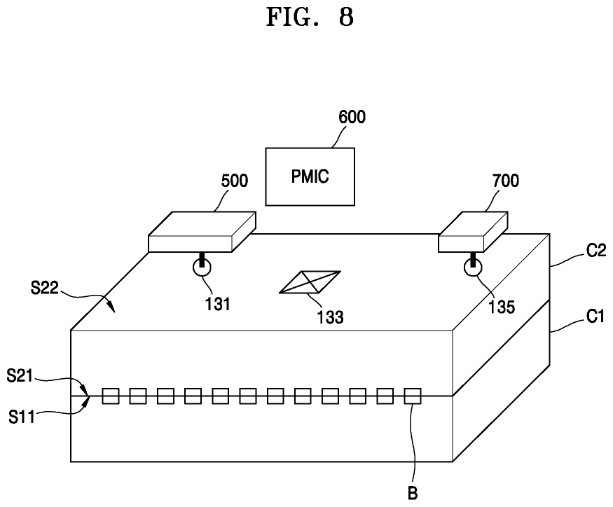

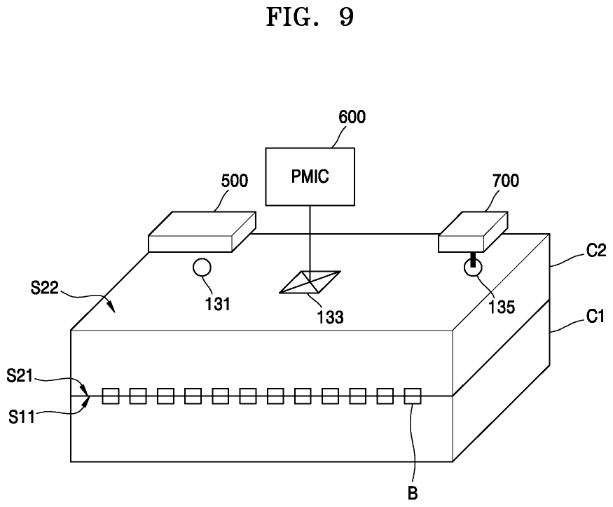

FIGS. 8 and 9 are perspective views illustrating an example structure of the memory device shown in FIG. 5, according to embodiments.

Referring to FIGS. 5, 8 and 9, a memory device 120 may include a first chip C1 and a second chip C2.

The first chip C1 may include a memory cell array 122. The first chip C1 may correspond to an upper chip including the cell region CELL of the embodiment of FIG. 3.

The second chip C2 may include a row decoder 394, a control circuit 124, a page buffer 393, an input/output circuit 126, a voltage generator 128, an auxiliary voltage generator 127, and a connection circuit 130, shown in FIGS. 3 and 5. The second chip C2 may correspond to a lower chip including the peripheral circuit area PERI of the embodiment of FIG. 3.

The second chip C2 may be connected to the first chip C1 through a bonding manner. When a bonding metal B is formed of copper, the bonding manner between the second chip C2 and the first chip C1 may be a Cu—Cu bonding manner and the bonding metal B may be formed of aluminum or tungsten. For example, the second chip C2 may be connected to the first chip C1 through Cu—Cu bonding.

The second chip C2 may include a first surface S21 and a second surface S22. The first surface S21 of the second chip C2 may be connected to the first chip C1. In this case, the first surface S21 of the second chip C2 may be connected to a first surface S11 of the first chip C1 by a bonding manner.

A bonding pad 131, a wire pad 133, and an auxiliary bonding pad 135 may be formed on the second surface S22 of the second chip C2. In this case, the bonding pad 131 may be connected to the voltage generator 128 through a bonding pad switch 132, the wire pad 133 may be connected to the voltage generator 128 through a wire pad switch 134, and the auxiliary bonding pad 135 may be connected to the auxiliary voltage generator 127 included in the memory device 120.

The bonding pad 131 may be connected to the charge pump 500 through a bonding manner. In this case, the charge pump 500 may be configured in the form of a chip, and a pad for bonding may be formed on one surface of the charge pump 500.

The wire pad 133 may be connected to a PMIC 600. The PMIC 600 may be one component of a device including the memory system 100, and the PMIC 600 may be connected to the wire pad 133 through a conductive wire.

The auxiliary bonding pad 135 may be connected to an auxiliary charge pump 700 through a bonding manner. In this case, the auxiliary charge pump 700 may be configured in the form of a chip, and a pad for bonding may be formed on one surface of the auxiliary charge pump 700.

In an embodiment, when the memory device 120 is included in a device that does not include the PMIC 600, such as a mobile device, the bonding pad 131 may be connected to the charge pump 500 through a bonding manner as shown in FIG. 8. In this case, the wire pad 133 may not be connected to the PMIC 600.

In an embodiment, when the memory device 120 is included in a device including the PMIC 600, such as an SSD, the bonding pad 131 may not be connected to the charge pump 500 as shown in FIG. 9. In this case, the wire pad 133 may be connected to the PMIC 600.

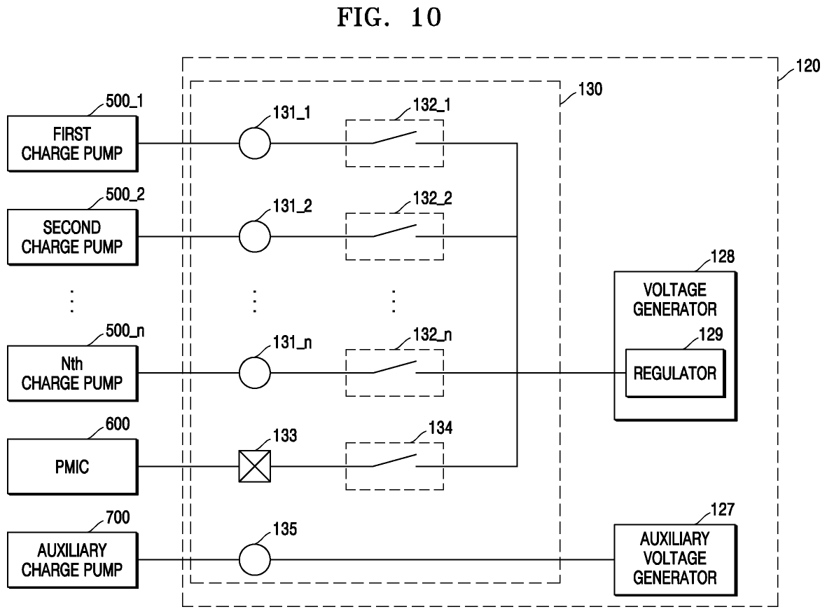

FIG. 10 is a circuit diagram illustrating another example of a connection circuit of a memory device according to an embodiment.

Referring to FIG. 10, a connection circuit 130 according to an embodiment may include a plurality of bonding pads 131_1 to 131_n, a plurality of bonding pad switches 132_1 to 132_n, a wire pad 133, a wire pad switch 134, and an auxiliary bonding pad 135.

Because a wire pad 133, a wire pad switch 134, and an auxiliary bonding pad 135 in the embodiment of FIG. 10 may operate in the same way as the wire pad 133, the wire pad switch 134, and the auxiliary bonding pad 135 in the embodiment of FIG. 5, the corresponding descriptions thereof may be omitted.

The plurality of bonding pads 131_1 to 131_n may be connected to the voltage generator 128. Because the plurality of bonding pads 131_1 to 131_n may be connected to the voltage generator 128, an external voltage supplied from the charge pump 500 outside the memory device 120 may be transferred to the voltage generator 128 through the plurality of bonding pads 131_1 to 131_n. The external voltage supplied through the plurality of bonding pads 131_1 to 131_n may be transferred to the regulator 129 of the voltage generator 128.

The plurality of bonding pads 131_1 to 131_n may be connected to the plurality of charge pumps 500_1 to 500_n through a bonding manner. For example, a first bonding pad 131_1 may be connected to the first charge pump 500_1 through a bonding manner, a second bonding pad 1312 may be connected to the second charge pump 500_2 through the bonding manner, and an nth bonding pad 131_n may be connected to the nth charge pump 500_n through the bonding manner. For example, the first bonding pad 131_1 may be bonded to the first charge pump 500_1, the second bonding pad 131_2 may be bonded to the second charge pump 500_2, and the nth bonding pad 131_n may be bonded to the nth charge pump 500_n.

In an embodiment, when the plurality of bonding pads 131_1 to 131_n are formed of copper, the bonding manner may be a Cu—Cu bonding manner and the plurality of bonding pads 131_1 to 131_n may also be formed of aluminum or tungsten.

All of the plurality of bonding pads 131_1 to 131_n may not be connected to the plurality of charge pumps 500_1 to 500_n, and one or more bonding pads among the plurality of bonding pads 131_1 to 131_n may be connected to a corresponding charge pump. In this case, the number of bonding pads connected to the plurality of charge pumps 500_1 to 500_n among the plurality of bonding pads 131_1 to 131_n may be proportional to the magnitude of the voltage used or required by the voltage generator 128. For example, when the magnitude of the voltage used of required by the voltage generator 128 is at a lowest level, only one bonding pad among the plurality of bonding pads 131_1 to 131_n may be connected to a corresponding charge pump by bonding. As another example, when the magnitude of the voltage used or required by the voltage generator 128 is at a maximum level, all of the plurality of bonding pads 131_1 to 131_n may be connected to a corresponding charge pump by bonding.

The plurality of bonding pad switches 132_1 to 132_n may be between the plurality of bonding pads 131_1 to 131_n and the voltage generator 128. One end of the plurality of bonding pad switches 132_1 to 132_n may be connected to the plurality of bonding pads 131_1 to 131_n and the other end of the plurality of bonding pad switches 132_1 to 132_n may be connected to the voltage generator 128.

The plurality of bonding pad switches 132_1 to 132_n may adjust a connection between the plurality of bonding pads 131_1 to 131_n and the voltage generator 128. The plurality of bonding pad switches 132_1 to 132_n may connect or disconnect the plurality of bonding pads 131_1 to 131_n and the voltage generator 128. For example, the first bonding pad switch 132_1 may connect or disconnect the first bonding pad 131_1 and the voltage generator 128, the second bonding pad switch 132_2 may connect or disconnect the second bonding pad 131_2 and the voltage generator 128, and the n-th bonding pad switch 132_n may connect or disconnect the n-th bonding pad 131_n and the voltage generator 128.

The plurality of bonding pad switches 132_1 to 132_n may adjust a connection between the plurality of bonding pads 131_1 to 131_n and the voltage generator 128 based on whether the voltage generator 128 receives external voltage from the charge pump 500 to operate.

When the voltage generator 128 operates by receiving voltage from the charge pump 500, the plurality of bonding pad switches 132_1 to 132_n may connect one or more bonding pads connected to the charge pump among the plurality of bonding pads 131_1 to 131_n to the voltage generator 128, and may disconnect a bonding pad not connected to the charge pump among the plurality of bonding pads 131_1 to 131_n and the voltage generator 128. In addition, when the voltage generator 128 receives voltage from the PMIC 600 to operate, the plurality of bonding pad switches 132_1 to 132_n may disconnect the plurality of bonding pads 131_1 to 131_n from the voltage generator 128.

The plurality of bonding pad switches 132_1 to 132_n may adjust a connection between the plurality of bonding pads 131_1 to 131_n and the voltage generator 128 based on a command received from an external controller. The plurality of bonding pad switches 132_1 to 132_n may adjust a connection between the plurality of bonding pads 131_1 to 131_n and the voltage generator 128 based on a command received from a controller that controls a device including the memory system 100.

For example, when the memory device 120 is included in a device that does not include the PMIC 600, such as a mobile device, the command received from the corresponding device may be a command for controlling a bonding pad switch connected to a bonding pad connected to a charge pump among the plurality of bonding pad switches 132_1 to 132_n to connect the bonding pad to the voltage generator 128 and may be a command for controlling a bonding pad switch connected to a bonding pad not connected to the charge pump among the plurality of bonding pad switches 132_1 to 132_n to disconnect the bonding pad from the voltage generator 128.

In addition, when the memory device 120 is included in a device including the PMIC 600, such as an SSD, the command received from the corresponding device may be a command for controlling the plurality of bonding pad switches 132_1 to 132_n to disconnect the plurality of bonding pads 131_1 to 131_n from the voltage generator 128, and accordingly, the plurality of bonding pad switches 132_1 to 132_n may disconnect the plurality of bonding pads 131_1 to 131_n from the voltage generator 128.

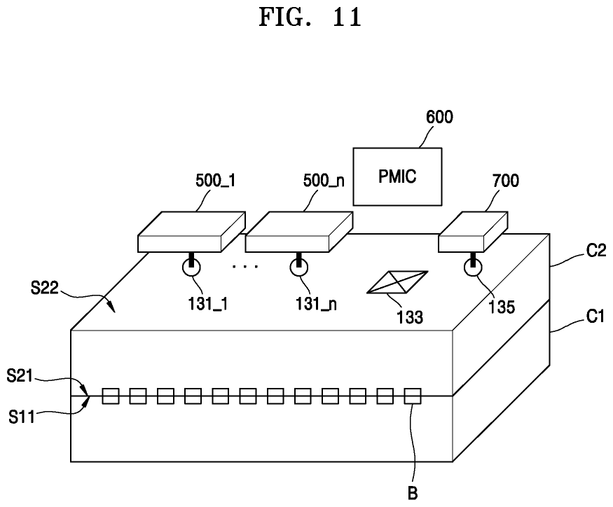

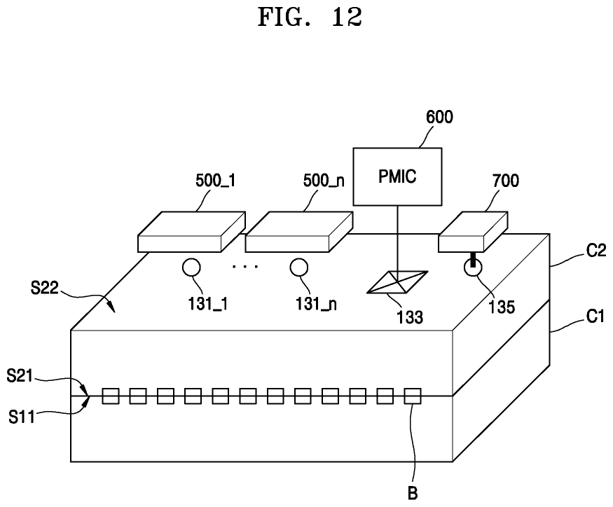

FIGS. 11 and 12 are perspective views illustrating examples of the structure of the memory device shown in FIG. 10, according to embodiments.

Referring to FIGS. 11 and 12, a memory device 120 may include a first chip C1 and a second chip C2. Because the first chip C1 and the second chip C2 of FIGS. 11 and 12 may be similar to the first chip C1 and the second chip C2 of FIG. 9, redundant or duplicative description may be omitted.

A plurality of bonding pads 131_1 to 131_n, a wire pad 133, and an auxiliary bonding pad 135 may be formed on a second surface S22 of the second chip C2. In this case, the plurality of bonding pads 131_1 to 131_n may be connected to the voltage generator 128 through the plurality of bonding pad switches 132_1 to 132_n.

The plurality of bonding pads 131_1 to 131_n may be connected to the plurality of charge pumps 500_1 to 500_n through a bonding manner, respectively. In this case, the plurality of charge pumps 500_1 to 500_n may be configured in a chip form, and a pad for bonding may be formed on one surface of the plurality of charge pumps 500_1 to 500_n.

In an embodiment, when the memory device 120 is included in a device that does not include the PMIC 600, such as a mobile device, at least one of the plurality of bonding pads 131_1 to 131_n may be connected to the plurality of charge pumps 500_1 to 500_n through a bonding manner, as shown in FIG. 11. In this case, the wire pad 133 may not be connected to the PMIC 600.

In an embodiment, when the memory device 120 is included in a device including the PMIC 600, such as an SSD, the plurality of bonding pads 131_1 to 131_n may not be connected to the plurality of charge pumps 500_1 to 500_n, as shown in FIG. 12. In this case, the wire pad 133 may be connected to the PMIC 600.

As described above, the memory system 100 according to an embodiment may include a plurality of bonding pads 131_1 to 131_n connected to the voltage generator 128 and connected to the external charge pump 500 in a bonding manner, and the charge pump 500 may be positioned outside the memory device 120, thereby minimizing an increase in size of the memory device 120 due to an increase in capacity of the memory device 120.

At least one of the components, elements, modules, units, or the like (collectively “components” in this paragraph) represented by a block or an equivalent indication (collectively “block”) in the above embodiments, for example, device, logic, controller, circuit, generator, detector, encoder, decoder, operator, latch, or the like, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein). These components may, for example, be embodied in one or more semiconductor chips, or on substrate supports such as printed circuit boards and the like. These circuits may also be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks. Likewise, the blocks of the embodiments may be physically combined into more complex blocks.

While the some embodiments have been particularly shown and described, it will be understood that various changes in form and details may be made therein without departing from the spirit and scope of the following claims.

What is claimed is:

1. A memory device comprising:
a first chip comprising a memory cell array; and
a second chip bonded to the first chip and comprising a voltage generator configured to generate a voltage which is supplied to the memory cell array,
wherein the second chip comprises a bonding pad connected to the voltage generator and bonded to an external charge pump.

2. The memory device of claim 1, wherein the second chip comprises:
a first surface bonded to the first chip; and
a second surface on which the bonding pad is formed.

3. The memory device of claim 1, wherein the second chip further comprises:
a bonding pad switch configured to adjust a connection between the bonding pad and the voltage generator;
a wire pad connected to the voltage generator in parallel with the bonding pad and connected to an external power management integrated circuit (PMIC); and
a wire pad switch configured to adjust a connection between the wire pad and the voltage generator.

4. The memory device of claim 3, wherein the second chip comprises:
a first surface bonded to the first chip; and
a second surface on which the bonding pad and the wire pad are formed.

5. The memory device of claim 3, wherein the bonding pad switch is further configured to connect the bonding pad to the voltage generator based on the voltage generator receiving voltage from the external charge pump, and
wherein the bonding pad switch is further configured to disconnect the bonding pad from the voltage generator based on the voltage generator receiving voltage from the PMIC.

6. The memory device of claim 3, wherein the wire pad switch is further configured to:
disconnect the wire pad from the voltage generator based on the voltage generator receiving voltage from the external charge pump, and
connect the wire pad to the voltage generator based on the voltage generator receiving voltage from the PMIC.

7. The memory device of claim 3,
wherein the bonding pad switch is configured to adjust the connection between the bonding pad and the voltage generator based on a command received from an external controller, and
wherein the wire pad switch is further configured to adjust the connection between the wire pad and the voltage generator based on a command received from the external controller.

8. The memory device of claim 1, wherein the second chip further comprises an auxiliary bonding pad bonded to peripheral circuits included in the second chip and bonded to an external auxiliary charge pump.

9. A memory device comprising:
a first chip comprising a memory cell array; and
a second chip bonded to the first chip;
wherein the second chip comprises:
a connection circuit supplied with an external voltage; and
a voltage generator configured to generate a voltage which is supplied to the memory cell array based on the external voltage,
wherein the connection circuit comprises:
a plurality of bonding pads connected to the voltage generator, wherein each bonding pad of the plurality of bonding pads is bonded to a corresponding external charge pump from among a plurality of external charge pumps;
a plurality of bonding pad switches configured to adjust a connection between the each bonding pad and the voltage generator;
a wire pad connected to the voltage generator in parallel with the plurality of bonding pads, and connected to an external power management integrated circuit (PMIC); and
a wire pad switch configured to adjust a connection between the wire pad and the voltage generator.

10. The memory device of claim 9, wherein the second chip comprises
a first surface bonded to the first chip; and
a second surface on which the plurality of bonding pads and the wire pad are formed.

11. The memory device of claim 9,
wherein, based on the voltage generator receiving voltage from the plurality of external charge pumps, one or more bonding pads from among the plurality of bonding pads are connected to the plurality of external charge pumps, and
wherein a number of the one or more bonding pads is proportional to a magnitude of an operating voltage used by the voltage generator.

12. The memory device of claim 11,
wherein the plurality of bonding pad switches are further configured to connect the one or more bonding pads to the voltage generator, and to disconnect remaining bonding pads from among the plurality of bonding pads from the voltage generator based on the voltage generator receiving voltage from the plurality of external charge pumps, and
wherein the plurality of bonding pad switches are further configured to disconnect the plurality of bonding pads from the voltage generator based on the voltage generator receiving voltage from the PMIC.

13. The memory device of claim 9, wherein the wire pad switch is further configured to disconnect the wire pad from the voltage generator based on the voltage generator receiving voltage from the plurality of external charge pumps, and connect the wire pad to the voltage generator based on the voltage generator receiving voltage from the PMIC.

14. The memory device of claim 9,
wherein the plurality of bonding pad switches are further configured to adjust a connection between the plurality of bonding pads and the voltage generator based on a command received from an external controller, and
wherein the wire pad switch is further configured to adjust the connection between the wire pad and the voltage generator based on the command received from the external controller.

15. The memory device of claim 9, wherein the second chip further comprises an auxiliary bonding pad connected to peripheral circuits included in the second chip, and bonded to an external auxiliary charge pump.

16. A memory system comprising:
a memory controller; and
a memory device configured to operate based on a command received from the memory controller,
wherein the memory device comprises:
a memory cell array;
a connection circuit supplied with an external voltage; and
a voltage generator configured to generate a voltage supplied to the memory cell array based on the external voltage,
wherein the connection circuit comprises:
a plurality of bonding pads connected to the voltage generator, wherein each bonding pad of the plurality of bonding pads is bonded to a corresponding external charge pump from among a plurality of external charge pumps;
a plurality of bonding pad switches configured to adjust a connection between the each bonding pad and the voltage generator;
a wire pad connected to the voltage generator in parallel with the plurality of bonding pads, and connected to an external power management integrated circuit (PMIC); and
a wire pad switch configured to adjust a connection between the wire pad and the voltage generator.

17. The memory system of claim 16,
wherein the memory cell array is included in a first chip,
wherein the connection circuit and the voltage generator are included in a second chip, and
wherein a first surface of the first chip is bonded to a first surface of the second chip.

18. The memory system of claim 17, wherein the plurality of bonding pads and the wire pad are formed on a second surface of the second chip.

19. The memory system of claim 16,
wherein, based on the voltage generator receiving voltage from the plurality of external charge pumps, one or more bonding pads from among the plurality of bonding pads are connected to the plurality of external charge pumps, and
wherein a number of the one or more bonding pads is proportional to a magnitude of an operating voltage used by the voltage generator.

20. The memory system of claim 16,
wherein the plurality of bonding pad switches are further configured to adjust the connection between the plurality of bonding pads and the voltage generator based on a command received from an external controller, and
wherein the wire pad switch is further configured to adjust the connection between the wire pad and the voltage generator based on the command received from the external controller.
